(19) United States
(12) Patent Application Publication
(10) Pub. No.: US 2013/0256247 A1
(43) Pub. Date: Oct. 3, 2013

(54) MOUNTING APPARATUS FOR DATA STORAGE DEVICE

(71) Applicants: HONG FU JIN PRECISION INDUSTRY (SHENZHEN) CO., LT, Shenzhen (CN); HON HAI PRECISION INDUSTRY CO., LTD., New Taipei (TW)

(72) Inventors: YU-WEI HE, Shenzhen (CN); XIU-QUAN HU, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/685,636

(22) Filed: Nov. 26, 2012

(30) Foreign Application Priority Data
Mar. 28, 2012 (CN) 201210085106.7

(51) Int. Cl. H05K 7/14

(52) U.S. Cl. CPC H05K 7/1417
USPC 211/41.12

(57) ABSTRACT

A mounting apparatus includes a chassis and a disk drive holder mounted in the chassis. The chassis include a base panel; a side panel, extending substantially perpendicularly from the base panel; and a mounting piece, extending substantially perpendicularly from the side panel. A pair of engaging tabs extends from the base panel and the mounting piece oppositely. The disk drive holder includes a pair of side plates. A pair of engaging slots is defined in the pair of side plates corresponding to the pair of engaging tabs. Each of the pair of engaging slots includes an entrance portion and an engaging portion connected with the entrance portion. The disk drive holder is movable between an unlocked position, where each of the pair of engaging tabs is engaged with the entrance portion, and a locked position, where each of the pair of engaging tabs is engaging with the engaging portion.

### BACKGROUND

1. Technical Field

The present disclosure relates to a mounting apparatus for a data storage device.

2. Description of Related Art

Data storage devices, such as hard disk drives, optical disk drives, etc., are widely used in computing devices. At least one disk drive bracket is mounted in a chassis of the computing devices for holding the data storage devices. The data storage devices can slide into or slide out from the at least one disk drive bracket. However, the at least one disk drive bracket is secured to the chassis by fasteners, which is very inconvenient.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric, exploded view of a mounting apparatus for a data storage device in accordance with an embodiment.

FIG. 2 is an assembled view of FIG. 1.

### DETAILED DESCRIPTION

The disclosure is illustrated by way of example and not by way of limitation. In the figures of the accompanying drawings, like references indicate similar elements. It should be noted that references to “an” or “one” embodiment in this disclosure are not necessarily to the same embodiment, and such references mean “at least one.”

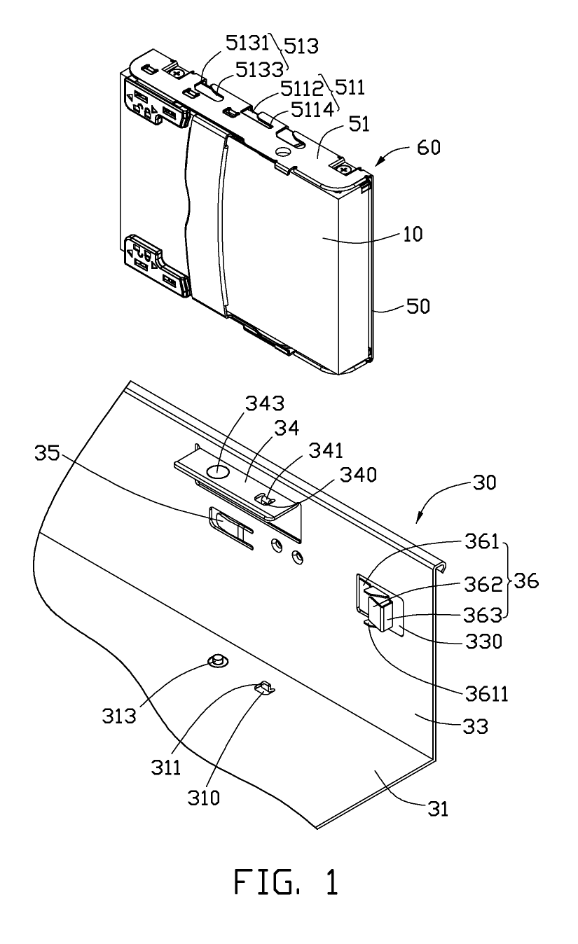

Referring to FIG. 1, an embodiment of a data storage device mounting assembly includes a chassis 30 and a data storage assembly 60. The data storage assembly 60 includes a disk drive holder 50 and a data storage device 10, mounted in the disk drive holder 50. In one embodiment, the data storage device 10 is a hard disk drive.

The chassis 30 includes a base panel 31 and a side panel 33 extending upwardly from a side edge of the base panel 31. The side panel 33 is substantially perpendicular to the base panel 31. A first opening 310 is defined in the base panel 31. A first engaging tab 311 extends upwardly from an edge of the first opening 310. The first engaging tab 311 is substantially parallel to the side panel 33. A first engaging post 313 protrudes upwardly from the base panel 31.

A mounting piece 34 extends substantially perpendicularly from the side panel 33 towards an inner side of the chassis 30. The mounting piece 34 has a substantially rectangular shape and is adjacent to a top edge of the side panel 33. A second opening 340 is defined in the mounting piece 34. A second engaging tab 341 extends downwardly from an edge of the second opening 340 corresponding to the first engaging tab 311. The mounting piece 34 has an engaging portion 343 from which a second engaging post (not shown) extending downwardly corresponding to the first engaging post 313. The side panel 33 includes a resilient resisting piece 35 located below the mounting piece 34.

A third opening 330 is defined in the side panel 33 and located adjacent to a front edge of the side panel 33. A resilient blocking piece 36 extends from a rear edge of the third opening 330 in a tortuous pattern. The resilient blocking piece 36 includes a main piece 361 extending forwardly from the rear edge of the third opening 330, a connecting piece 363 extending substantially perpendicularly from a front edge of the main piece 361 toward the inner side of chassis 30, and a distal flange 362 extending slantways from the connecting piece 363 towards a rear side of the side panel 33. The main piece 361 is flat or slightly tilted relative to the side panel 33. A pair of blocking pieces 3611 extends substantially perpendicularly from upper and lower edges of the main piece 361 towards the inner side of the chassis 30. Each of the pair of blocking pieces 3611 has a trapezoidal shape. The distal flange 362 is adjacent to and located between the pair of blocking pieces 3611.

The disk drive holder 50 includes a base plate and a pair of side plates 51 extending substantially perpendicularly from opposite side edges of the base plate. A distance between the pair of side plates 51 is substantially equal to the distance between the mounting piece 34 and the base panel 31. A first engaging slot 511 and a second engaging slot 513 are defined in each of the pair of side plates 51. The first engaging slot 511 includes a first entrance portion 5112 and a first engaging portion 5114 connecting with the entrance portion 5112. The second engaging slot 513 includes a second entrance portion 5131 and a second engaging portion 5133 connecting with the entrance portion 5112. A thickness of each of the first engaging tab 311 and the second engaging tab 341 is substantially equal to a width of the first engaging portion 5114. A diameter of each of the first engaging post 313 and the second engaging post is substantially equal to a width of the second engaging portion 5133.

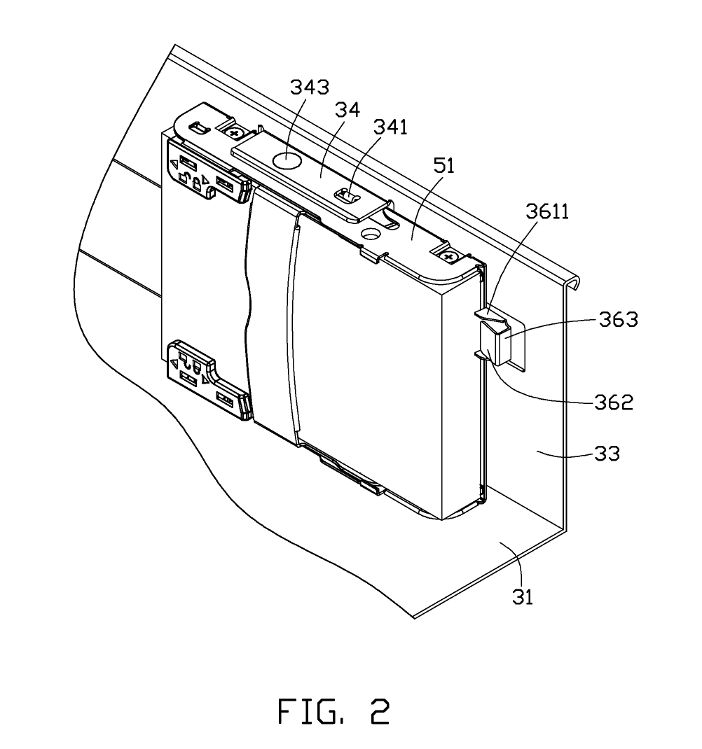

Referring to FIGS. 1 and 2, in assembly, the data storage assembly 60 is placed on the base panel 31. The pair of side plates 51 is substantially perpendicular to the side panel 33. The first entrance portions 5112 of the pair of side plates 51 is aligned with the first engaging tab 311 and the second engaging tab 341. The second entrance portions 5131 of the pair of side plates 51 is aligned with the first engaging post 313 and the second engaging post at the engaging portion 343. The data storage assembly 60 is moved along a first direction that is substantially perpendicular to the side panel 33. The first engaging tab 311 and the second engaging tab 341 enter in the first entrance portions 5112 of the pair of side plates 51. The first engaging post 313 and the second engaging post at the engaging portion 343 enter in the second entrance portions 5131 of the pair of side plates 51. The disk drive holder 50 resists against the resilient resisting piece 35 and the resilient blocking piece 36. The resilient resisting piece 35 can damp vibration of the data storage device 10 and provide EMI shielding for the data storage device 10. The resilient blocking piece 36 is deformed and moved towards an outside of the side panel 33 via the third opening 330. The data storage assembly 60 is moved backwards along a second direction until reaching a locked position. The second direction is substantially parallel to the base panel 31 and the side panel 33. In the locked position, the first engaging tab 311 and the second engaging tab 341 are engaged with the first engaging portions 5114 of the pair of side plates 51; and the first engaging post 313 and the second engaging post at the engaging portion 343 are engaged with the second engaging portions 5133 of the pair of side plates 51. The resilient blocking piece 36 returns to its original state since the disk drive holder 50 moves away from the pair of blocking pieces 3611. The pair of blocking pieces 3611 and the distal flange 362 resists the data storage assembly 60, thereby preventing the data storage assembly 60 moving away from the locked position.

In disassembly, the distal flange 362 is pressed. The resilient blocking piece 36 is deformed and moved towards the outside of the side panel 33. The pair of blocking pieces 3611 does not block the data storage assembly 60. The data storage assembly 60 is moved forwardly until reaching an unlocked position, where the first engaging tab 311 and the second engaging tab 341 are moved to the first entrance portions 5112, and the first engaging post 313 and the second engaging post are moved to the second entrance portions 5131. Then the data storage assembly 60 can detached from the chassis 30.

While the present disclosure has been illustrated by the description in this embodiment, and while the embodiment has been described in considerable detail, it is not intended to restrict or in any way limit the scope of the appended claims to such details. Additional advantages and modifications within the spirit and scope of the present disclosure will readily appear to those skilled in the art. Therefore, the present disclosure is not limited to the specific details and illustrative examples shown and described.

What is claimed is:

1. A mounting apparatus comprising:
a chassis comprising a base panel and a side panel, extending substantially perpendicularly from the base panel; a mounting piece extending substantially perpendicularly from the side panel; a pair of engaging tabs extending from the base panel and the mounting piece oppositely; and an opening being defined in the side panel, and a resilient blocking piece extending from an edge of the opening in a tortuous pattern; and
a disk drive holder, adapted for holding a data storage device, comprising a pair of side plates; and a pair of first engaging slots being defined in the pair of side plates corresponding to the pair of engaging tabs, each of the pair of first engaging slots comprising a first entrance portion and a first engaging portion connected with the first entrance portion;
wherein the disk drive holder is movable between an unlocked position, where each of the pair of engaging tabs is engaged with the first entrance portion, and the resilient blocking piece is deformed by the disk drive holder, and a locked position, where each of the pair of engaging tabs is engaging with the first engaging portion, and the resilient blocking piece returns to its original state and resists against the disk drive holder, thereby preventing the disk drive holder moving from the locked position to the unlocked position.

2. The mounting apparatus of claim 1, wherein the resilient blocking piece comprises a main piece, extending from the edge of the opening, towards a front side of the side panel; a connecting piece, extending substantially perpendicularly from the main piece towards an inner side of chassis; and a distal flange, extending slantways from the connecting piece, towards a rear side of the side panel.

3. The mounting apparatus of claim 2, wherein the main piece is flat relative to the side panel.

4. The mounting apparatus of claim 3, wherein a pair of blocking pieces extends substantially perpendicularly from upper and lower edges of the main piece towards the inner side of the chassis, and the pair of blocking pieces resists against the disk drive holder in the locked position.

5. The mounting apparatus of claim 1, wherein a pair engaging posts extends from the base panel and the mounting piece, and a pair of second engaging slots is defined in the pair of side plates corresponding to the pair of engaging posts.

6. The mounting apparatus of claim 5, wherein each of the pair of second engaging slots comprises a second entrance portion and a second engaging portion connecting with the second entrance portion, each of the pair of engaging posts is engaged with the second entrance portion in the unlocked position, and each of the pair of engaging posts is engaged with the second engaging portion in the locked position.

7. The mounting apparatus of claim 1, wherein a distance between the mounting piece and the base panel is substantially equal to that between the pair of side plates.

8. The mounting apparatus of claim 1, wherein the pair of engaging tabs is substantially parallel to the side panel, and a thickness of each of the pair of engaging tabs is substantially equal to a width of the first engaging portion.

9. The mounting apparatus of claim 1, wherein the side panel comprises a resilient resisting piece that is located below the mounting piece and resists against the disk drive holder.

10. A mounting apparatus comprising:
a chassis comprising a base panel; a side panel, extending substantially perpendicularly from the base panel; a mounting piece, extending substantially perpendicularly from the side panel; and an engaging tab, extending from the mounting piece towards the base panel; and an opening being defined in the side panel, and a resilient blocking piece extending from an edge of the opening in a tortuous pattern; and
a disk drive holder, adapted for holding a data storage device, comprising a base plate and a first side plate extending substantially perpendicularly from the base plate; and a first engaging slot being defined in the first side plate corresponding to the engaging tab, the first engaging slot comprises a first entrance portion and a first engaging portion that is connected to the first entrance portion;
wherein the disk drive holder is movable between an unlocked position, where the engaging tab is engaged with the first entrance portion, and the resilient blocking piece is deformed by the disk drive holder, and a locked position, where the engaging tab is engaging with the first engaging portion, and the resilient blocking piece returns to its original state and resists against the disk drive holder, thereby preventing the disk drive holder moving from the locked position to the unlocked position.

11. The mounting apparatus of claim 10, wherein the resilient blocking piece comprises a main piece, extending from the edge of the opening, towards a front side of the side panel; a connecting piece, extending substantially perpendicularly from the main piece towards an inner side of chassis; and a distal flange, extending slantways from the connecting piece, towards a rear side of the side panel.

12. The mounting apparatus of claim 11, wherein the main piece is slightly tilted relative to the side panel.

13. The mounting apparatus of claim 12, wherein a pair of blocking pieces extends substantially perpendicularly from upper and lower edges of the main piece towards the inner side of the chassis, and the pair of blocking pieces resists against the disk drive holder in the locked position.

14. The mounting apparatus of claim 10, wherein an engaging post extends from the base panel towards the mounting piece, and a second engaging slot is defined in the first side plate corresponding to the engaging post.

15. The mounting apparatus of claim 14, wherein the second engaging slot comprises a second entrance portion and a second engaging portion connected to the second entrance portion, the engaging post is engaged with the second entrance portion in the unlocked position, and the engaging post is engaged with the second engaging portion in the locked position.

16. The mounting apparatus of claim 10, wherein the disk drive holder further comprises a second side plate located at an opposite side relative to the first side plate, the second side plate is placed on the base panel.

17. The mounting apparatus of claim 10, wherein the engaging tab is substantially parallel to the side panel, and a thickness of the engaging tab is substantially equal to a width of the first engaging portion.

18. The mounting apparatus of claim 10, wherein the side panel comprises a resilient resisting piece that is located below the mounting piece and resists against the base plate.
